(19) United States
(12) Patent Application Publication
(10) Pub. No.: US 2023/0235194 A1
(43) Pub. Date: Jul. 27, 2023

(54) POLISHING METHOD AND POLISHING COMPOSITION SET

(71) Applicant: FUJIMI INCORPORATED, Aichi (JP)

(72) Inventor: Shinichiro TAKAMI, Aichi (JP)

(21) Appl. No.: 17/927,089

(22) PCT Filed: May 24, 2021
(86) PCT No.: PCT/JP2021/019631

§ 371 Date: Nov. 22, 2022

(30) Foreign Application Priority Data
May 27, 2020 (JP) 2020-092648

(51) Int. Cl. C09G 1/02; B24B 37/04; C09K 3/14

(52) U.S. Cl. CPC C09G 1/02; B24B 37/044; C09K 3/1409

(57) ABSTRACT

Provided is a polishing method that can efficiently achieve a surface of a super-hard material from which latent defects are precisely eliminated. The polishing method provided by the present invention is used for polishing a substrate made of a material having a Vickers hardness of 1500 Hv or higher. The polishing method includes: a step of carrying out preliminary polishing on the substrate using a preliminary polishing composition; and a step of carrying out final polishing on the preliminarily polished substrate using a final polishing composition. Here, a surface roughness Ra_{PRE} of the preliminarily polished substrate measured by an AFM is 0.1 nm or less, and a polishing removal in the final polishing step is 0.3 µm or more.

### TECHNICAL FIELD

The present invention relates to a polishing method and a polishing composition kit. In particular, it relates to a method for polishing a substrate made of a super-hard material such as single crystal silicon carbide and to a polishing composition kit used in the polishing method. The present application claims priority to Japanese Patent Application No. 2020-92648 filed on May 27, 2020; and the entire contents thereof are incorporated herein by reference.

### BACKGROUND ART

With regard to super-hard materials such as diamond, sapphire (aluminum oxide), silicon carbide, boron carbide, tungsten carbide, silicon nitride and titanium nitride, the surface of a substrate made of such a super-hard material is typically smoothed by a polishing (lapping) process in which diamond abrasives are supplied to a polishing platen. However, the lapping process using diamond abrasives causes scratches and leaves residual scratches, which limits the improvement in surface smoothness. Thus, studies are underway for a polishing process (polishing) that is carried out after or instead of the lapping with diamond abrasives using a polishing pad while supplying a polishing slurry between the polishing pad and a substrate. An example of literature in which this kind of related art is disclosed includes Patent Document 1.

### CITATION LIST

### Patent Literature

[Patent Document 1] WO 2016/072370

### SUMMARY OF INVENTION

### Technical Problem

Patent Document 1 discloses a polishing method of a substrate made of a super-hard material such as single crystal silicon carbide, the method including two steps of: carrying out preliminary polishing using a preliminary polishing composition; and carrying out final polishing using a final polishing composition. According to this polishing method, both smoothness and flatness can be efficiently achieved on the surface of the substrate made of a super-hard material.

The polishing of the substrate made of the super-hard material described above would be practically useful if an even higher level of surface quality is obtainable. The present invention has been made in view of the above circumstances, and an object of the present invention is to provide a polishing method that can achieve excellent surface quality for a substrate made of a super-hard material. Specifically, the present invention has an object to provide a polishing method that can efficiently achieve a surface of a substrate from which minute defects like latent defects that are difficult to be detected by observation with a wafer defect inspection device are precisely eliminated for the substrate made of a super-hard material. Another related object is to provide a polishing composition kit.

### Solution to Problem

The inventors have focused on the fact that, in a polishing method of a substrate made of a super-hard material, including preliminary polishing and final polishing, minute defects (latent defects) that are difficult to be detected by normal observation methods are more likely to occur on a superficial layer including the surface of the substrate preliminarily polished. Further, the inventors have found that the final polishing following the preliminary polishing allows the precise removal of the latent defects from the superficial layer of the substrate, which contributes to obtaining an even higher level of surface quality in the substrate made of a super-hard material. Based on the above findings, the present invention has been completed.

According to the present invention, there is provided a method for polishing a substrate made of a material having a Vickers hardness of 1500 Hv or higher. The polishing method includes: a step of carrying out preliminary polishing on the substrate using a preliminary polishing composition; and a step of carrying out final polishing on the preliminarily polished substrate using a final polishing composition. Here, a surface roughness Ra_{PRE} of the preliminarily polished substrate measured by an Atomic Force Microscope (AFM) is 0.1 nm or less. A polishing removal in the above final polishing step is 0.3 µm or more.

Such a polishing method can easily achieve a surface of a substrate made of a super-hard material from which latent defects are precisely eliminated. By eliminating latent defects from the surface, the surface roughness of the substrate made of the above super-hard material tends to decrease. Therefore, the above polishing method can achieve the surface with excellent smoothness in the substrate made of the super-hard material.

In a preferred embodiment of the polishing method disclosed herein, the above preliminary polishing composition contains an abrasive A_{PRE}. As the abrasive A_{PRE}, alumina particles can be preferably used. In a preferred embodiment, the above preliminary polishing composition further contains a polishing aid B_{PRE}. As the polishing aid B_{PRE}, for example, a composite metal oxide can be preferably used. By carrying out the preliminary polishing using the preliminary polishing composition with such a configuration, the polishing method is used for the polishing of a substrate made of a super-hard material and thus can efficiently achieve a surface of the substrate showing a preferable surface roughness Ra_{PRE}.

In a preferred embodiment of the polishing method disclosed herein, the above final polishing composition contains an abrasive A_{FIN}. As the abrasive A_{FIN}, for example, silica particles can be preferably used. With such a configuration, the polishing method is used for the polishing of a substrate made of a super-hard material and thus can easily achieve a surface of a high quality from which latent defects are suitably eliminated.

In another preferred embodiment of the polishing method disclosed herein, the above final polishing composition contains no abrasive A_{FIN}. When using the final polishing composition that does not contain the above abrasive A_{FIN}, a surface with excellent smoothness from which latent defects are suitably eliminated can be achieved easily and efficiently.

In a preferred embodiment of the polishing method disclosed herein, the above final polishing composition contains a polishing aid B_{FIN} As the polishing aid B_{FIN}, for example, a composite metal oxide can be preferably used. When using the final polishing composition with such a configuration, a surface with excellent smoothness from which latent defects are suitably eliminated can be achieved easily and efficiently.

According to the present invention, a polishing composition kit is provided which includes any of the preliminary polishing compositions disclosed herein and any of the final polishing compositions disclosed herein. When using the polishing composition kit with such a configuration, a surface with excellent smoothness from which latent defects are suitably eliminated can be achieved easily and efficiently.

### DESCRIPTION OF EMBODIMENTS

Preferred embodiments of the present invention will be described below. Incidentally, matters that are other than those particularly mentioned herein but are necessary for implementation of the present invention can be recognized by those skilled in the art as design matters based on the prior art in the relevant field. The present invention can be implemented based on the contents disclosed in this description and common technical knowledge in the subject field.

A polishing method disclosed herein includes: a step of carrying out preliminary polishing using a preliminary polishing composition (preliminary polishing step); and a step of carrying out final polishing using a final polishing composition (final polishing step). Hereinafter, a substrate to be polished, the polishing method, the preliminary polishing composition, and the final polishing composition will be described in this order.

### Substrate to Be Polished

The polishing method disclosed herein is a method of polishing a substrate made of a material having a Vickers hardness of 1500 Hv or higher (also referred to as a super-hard material). According to the polishing method disclosed herein, latent defects are removed from the surface of substrate made of the above super-hard material, whereby the smoothness of the surface is improved. The Vickers hardness of the super-hard material is preferably 1800 Hv or higher (e.g., 2000 Hv or higher, typically 2200 Hv or higher). The upper limit of Vickers hardness is not particularly limited, but it can be about 7000 Hv or lower (e.g., 5000 Hv or lower, typically 3000 Hv or lower). Herein, the Vickers hardness can be determined based on JIS R 1610:2003. The international standard corresponding to the above JIS standard is ISO 14705:2000.

Examples of the material having a Vickers hardness of 1500 Hv or higher include diamond, sapphire (aluminum oxide), silicon carbide, boron carbide, tungsten carbide, silicon nitride, titanium nitride, and the like. The polishing method disclosed herein can be preferably applied to a single crystal surface of the above material that is mechanically and chemically stable. Among these, a substrate surface to be polished is preferably formed of silicon carbide. Silicon carbide is expected to be a material for semiconductor substrates with little power loss, excellent heat resistance, etc. Thus, it is particularly advantageous to improve its surface conditions for practical use. The polishing method disclosed herein is particularly preferably applied to the surface of a single crystal silicon carbide.

### Polishing Method

The polishing method disclosed herein includes: a step of carrying out preliminary polishing (preliminary polishing step); and a step of carrying out final polishing (final polishing step). In the preliminary polishing step, the preliminary polishing is carried out on a substrate made of a material having a Vickers hardness of 1500 Hv or higher on at least its surface (surface to be polished) using the preliminary polishing composition. In the final polishing step, the final polishing is carried out on the preliminarily polished substrate using the final polishing composition.

In the polishing method including the preliminary polishing and the final polishing described above, it is advantageous that the total polishing time, which is the sum of the polishing time in preliminary polishing and the polishing time in final polishing, is not too long from the viewpoint of substrate production efficiency. Thus, preliminary polishing tends to be carried out with an emphasis on polishing removal rate. Further, final polishing tends to be ended when the surface quality of a substrate, such as smoothness, appears to become stable. However, according to the inventor’s studies, it has been found that minute defects (latent defects), which are difficult to be detected by observation with a general wafer defect inspection device, tend to be present on the superficial layer of the preliminarily polished substrate. It has been also found that conventional polishing methods may not be able to sufficiently remove latent defects because they do not pay attention to the presence of latent defects as such a minute level of defects. Therefore, it has been found that the surface of the substrate with an even higher level of excellent surface quality can be eventually achieved by carrying out final polishing on the preliminarily polished substrate not only simply until the surface quality (typically smoothness) of the substrate becomes stable, but also further with the goal of removing latent defects hidden in the superficial layer of the substrate.

As used herein, “latent defects” refer to defects that are not detected by observation with the general wafer defect inspection device and have a size of approximately 20 Å or more in the depth direction. For example, “latent defects” in a SiC wafer refer to defects not detected by observation with a SiC wafer defect inspection/review device (type: SICA6X) manufactured by Lasertec Corporation, and having a size of approximately 20 Å or more in the depth direction of the wafer.

According to the inventor’s studies, it has been found that many latent defects tend to be present mostly in the superficial layer region of approximately 0.3 µm or less in the depth direction from the substrate surface having a surface roughness of about 0.1 nm or less, as measured by the AFM. Because of this, for example, if the polishing removal for the final polishing following the preliminary polishing is set to be less than 0.3 µm in the substrate whose surface roughness is adjusted to be 0.1 nm or less by the preliminary polishing, some latent defects are left without being sufficiently removed from the superficial layer of the substrate. This makes it more difficult to improve the surface quality. In addition, conversely, latent defects hidden inside may be newly exposed to a surface subjected to the polishing, degrading the surface quality.

In the art disclosed herein, final polishing is carried out so that the polishing removal is 0.3 µm or more. By setting the polishing removal in the final polishing (hereinafter also referred to as a polishing removal W_{FIN}) to 0.3 µm or more, latent defects on the superficial layer of the preliminarily polished substrate tend to be removed suitably. From the viewpoint of improvement in elimination of latent defects, in some preferred embodiments, the polishing removal W_{FIN} in the final polishing may be more than 0.3 µm, 0.32 µm or more, 0.35 µm or more, 0.4 µm or more, or 0.42 µm or more. The substrate surface from which latent defects are suitably eliminated tends to have lower surface roughness and improved smoothness.

The upper limit of the polishing removal W_{FIN} in the final polishing is not particularly limited. From the viewpoint of efficiently removing latent defects from the superficial layer of the substrate without increasing the total polishing time too much, the polishing removal W_{FIN} in the final polishing is usually appropriate to be 2 µm or less, preferably 1.5 µm or less, more preferably 1 µm or less, and even more preferably 0.8 µm or less (e.g., 0.5 µm or less).

The polishing removal as used herein can be calculated using the following formula (a) by measuring a difference in the weight of the substrate before and after the polishing.

(a) polishing removal = difference in the weight of substrate before and after polishing/substrate density/substrate area

In the polishing method disclosed herein, the surface roughness of the substrate measured by the AFM after the final polishing (hereinafter also referred to as a “surface roughness Ra_{FIN}”) is not particularly limited. In a preferred embodiment of the art disclosed herein, the final polishing is carried out such that the surface roughness Ra_{FIN} is less than 0.06 nm, and more preferably 0.05 nm or less. In this way, the final polishing is performed such that the surface roughness Ra_{FIN} is less than or equal to a predetermined value (or less than a predetermined value), thereby making it possible to achieve a surface with excellent smoothness. From the viewpoint of not reducing productivity too much, the surface roughness Ra_{FIN} after the final polishing may be 0.01 nm or more, 0.02 nm or more, 0.03 nm or more, or 0.035 nm or more.

In the polishing method disclosed herein, the preliminary polishing is carried out using the preliminary polishing composition such that the surface roughness of the substrate measured by the AFM after the preliminary polishing (hereinafter also referred to as a “surface roughness Ra_{PRE}”) is 0.1 nm or less. By carrying out the preliminary polishing so as to achieve the surface roughness Ra_{PRE} of 0.1 nm or less, the subsequent final polishing can efficiently remove latent defects from the superficial layer of the substrate.

From the viewpoint of improvement in elimination of latent defects by the final polishing, the surface roughness Ra_{PRE} of the substrate after the preliminary polishing is preferably 0.09 nm or less, more preferably 0.08 nm or less, and even more preferably 0.07 nm or less (for example, 0.065 nm or less).

The lower limit of the surface roughness Ra_{PRE} after the preliminary polishing is not particularly limited. From the viewpoint of efficiently improving the smoothness of the substrate surface without increasing the total polishing time too much, the surface roughness Ra_{PRE} of the substrate after the preliminary polishing is normally appropriate to be 0.03 nm or more, and is preferably more than 0.04 nm, more preferably 0.045 nm or more, and even more preferably 0.05 nm or more (for example, 0.055 nm or more).

According to the polishing method disclosed herein, latent defects in the superficial layer of the preliminarily polished substrate are removed sufficiently by the final polishing, so that the surface roughness Ra_{FIN} of the substrate after the final polishing tends to become smaller than that of the substrate after the preliminary polishing. In a preferred embodiment, a value obtained by subtracting the surface roughness Ra_{FIN} [nm] from the surface roughness Ra_{PRE} [nm] is more than 0 nm, more preferably 0.005 nm or more, even more preferably 0.01 nm or more, and particularly preferably 0.015 nm or more. From the viewpoint of efficiently improving the smoothness of the substrate surface without increasing the total polishing time too much, the value obtained by subtracting the surface roughness Ra_{FIN} [nm] from the surface roughness Ra_{PRE} [nm] may be normally 0.09 nm or less, 0.08 nm or less, 0.07 nm or less, 0.06 nm or less, or 0.05 nm or less.

The surface roughness of the substrate mentioned herein (including the surface roughness Ra_{PRE} and the surface roughness Ra_{FIN}) is measured using the Atomic Force Microscope (AFM). Specifically, it is measured by a method described in Examples below.

In the art disclosed herein, the polishing removal in the preliminary polishing (hereinafter also referred to as a “polishing removal W_{PRE}”) is not particularly limited. In order to control the surface roughness Ra_{PRE} after the preliminary polishing within the preferred range described above, the polishing removal W_{PRE} in the preliminary polishing is normally appropriate to be 0.1 µm or more, and is preferably 0.3 µm or more, more preferably 0.4 µm or more, and even more preferably 0.5 µm or more. From the viewpoint of efficiently obtaining a surface with excellent smoothness without increasing the total polishing time too much, the polishing removal W_{PRE} in the preliminary polishing is usually appropriate to be 3 µm or less, and is preferably 2 µm or less, more preferably 1.8 µm or less, and even more preferably 1.5 µm or less.

In the above polishing method, a preliminary polishing slurry containing any of the preliminary polishing compositions disclosed herein is prepared. Further, a final polishing slurry containing any of the final polishing compositions disclosed herein is prepared. Preparation of the above slurry may include use of each polishing composition as the polishing slurry (polishing solution) as it is, or preparation of a polishing slurry by performing operations such as content adjustment (for example, dilution) and pH adjustment on each polishing composition.

The preliminary polishing is carried out using the prepared preliminary polishing slurry. Specifically, the preliminary polishing slurry is supplied to the substrate surface made of a super-hard material, and this surface is polished by a typical method. For instance, a substrate subjected to a lapping process is set in a general polishing machine, and the preliminary polishing slurry is supplied to the substrate surface via a polishing pad in the polishing machine. Typically, while the preliminary polishing slurry is continuously supplied, the polishing pad is pushed against the substrate surface, and both the surface and pad are moved (e.g., rotated) relative to each other.

Next, the final polishing is carried out using the prepared final polishing slurry. Specifically, the final polishing slurry is supplied to the substrate surface made of the super-hard material, and this surface is polished by a typical method. The final polishing is carried out by supplying the final polishing slurry to the substrate surface obtained after the preliminary polishing, via a polishing pad in the polishing machine. Typically, while the final polishing slurry is continuously supplied, the polishing pad is pushed against the substrate surface, and both of the surface and the pad are moved (e.g., rotated) relative to each other. Through the polishing steps described above, the polishing of the super-hard material is completed.

As used herein, the preliminary polishing step refers to a polishing step that is carried out before a final polishing step using a polishing slurry. In a typical embodiment, the preliminary polishing step is a polishing step that is arranged immediately before the final polishing step. The preliminary polishing step can be a polishing step having a single polishing step or a polishing step having two or more polishing substeps.

As used herein, the final polishing step refers to a polishing step that is arranged at last (i.e., on the most downstream side) among polishing steps carried out using polishing slurries. Accordingly, the final polishing composition disclosed herein can be thought as a kind of polishing slurry that is used on the most downstream side among polishing slurries used in a polishing process of a substrate made of a super-hard material.

The conditions of the preliminary polishing and the final polishing are appropriately selected based on the substrate, desired surface conditions, the polishing removal rate, and the like as well as technical common knowledge among those ordinarily skilled in the art. For instance, from the viewpoint of the polishing removal rate, the polishing pressure applied per cm² of a processed area of the substrate is preferably 50 g or more, or more preferably 100 g or more. From the viewpoint of preventing alteration of the substrate surface and degradation of abrasives due to excessive heat generated with increasing load, the polishing pressure per cm² of the processed area is usually appropriate to be 2000 g or less.

Linear velocity can generally change due to influences of the number of rotations of the platen, the number of rotations of carrier, the size of the substrate, the number of substrates, etc. With increasing linear velocity, a higher polishing removal rate tends to be obtained. From the viewpoint of preventing damage to the substrate and excessive heat generation in the substrate, the linear velocity can be limited to or below a certain level. The linear velocity can be selected based on technical common knowledge and is not particularly limited. It is preferably in the range of about 10 to 1500 m/min, or more preferably in the range of 50 to 1200 m/min.

The amount of the polishing composition to be supplied during polishing is not particularly limited. The above supply amount is desirably set so that the amount of the polishing composition is enough to be supplied evenly and entirely over the substrate surface. The favorable supply amount may also vary depending on the material of the substrate, the features of the polishing machine, and other conditions. For instance, the supply amount per mm² of the process area of the substrate is preferably in the range of 0.001 to 0.1 mL/min, or more preferably in the range of 0.002 to 0.03 mL/min.

Polishing time for the preliminary polishing (hereinafter also referred to as polishing time T_{PRE}) is not particularly limited as long as the surface roughness Ra_{PRE} of the substrate after the preliminary polishing is 0.1 nm or less. From the viewpoint of not increasing the total polishing time too long, the polishing time T_{PRE} in the polishing method disclosed herein is normally appropriate to be less than 3 hours. In a preferred embodiment, the polishing time T_{PRE} may be 2.5 hours or less, more preferably 2 hours or less, and even more preferably 1.5 hours or less (e.g., 1 hour or less). From the viewpoint of improving smoothness, in a preferred embodiment of the polishing method disclosed herein, the polishing time T_{PRE} for the preliminary polishing is typically 2 minutes or more, and may be, for example, 15 minutes or more, 30 minutes or more, or 45 minutes or more.

Polishing time for the final polishing (hereinafter also referred to as polishing time T_{FIN}) is not particularly limited as long as the polishing removal in the final polishing is 0.3 µm or more. From the viewpoint of not increasing the total polishing time too long in the polishing method disclosed herein, the polishing time T_{FIN} for the final polishing is normally appropriate to be less than 3 hours. In a preferred embodiment of the polishing method disclosed herein, the polishing time T_{FIN} for the final polishing may be 2.5 hours or less, more preferably 2 hours or less, and even more preferably 1.5 hours or less (e.g., 1 hour or less). From the viewpoint of improving smoothness, in a preferred embodiment of the polishing method disclosed herein, the polishing time T_{FIN} for the final polishing is typically 1 minute or more, and may be, for example, 5 minutes or more, 10 minutes or more, or 30 minutes or more.

Favorable polishing time can be set according to the polishing composition, polishing conditions, etc. For example, when the preliminary polishing composition contains abrasives (typically alumina particles), the polishing time T_{PRE} for the preliminary polishing is preferably set to 2 minutes or more and 60 minutes or less. In some embodiments, the polishing time T_{PRE} can be set to, for example, more than 2 minutes and 45 minutes or less, and can also be set to 3 minutes or more and 10 minutes or less.

For example, when the final polishing composition contains a vanadate as a polishing aid, the polishing time T_{FIN} for the final polishing is preferably set to 5 minutes or more and 90 minutes or less. In some embodiments, the polishing time T_{FIN} can be set to, for example, 6 minutes or more and 50 minutes or less, and can also be set to 7 minutes or more and 40 minutes or less. When the final polishing composition contains a permanganate as a polishing aid, the polishing time T_{FIN} for the final polishing is preferably set to 1 minute or more and 20 minutes or less. In some embodiments, the polishing time T_{FIN} can be set to, for example, more than 1 minute and 15 minutes or less, and can also be set to 2 minutes or more and 5 minutes or less.

In the polishing method disclosed herein, when the preliminary polishing composition contains a permanganate as the polishing aid while the final polishing composition contains a vanadate as the polishing aid, the ratio (T_{FIN}/T_{PRE}) of the polishing time T_{FIN} [min] for the final polishing to the polishing time T_{PRE} [min] for the preliminary polishing is preferably 1.0 or more, more preferably 1.1 or more, and even more preferably 1.2 or more. From the viewpoint of productivity, the above ratio (T_{FIN}/T_{PRE}) is typically 3.0 or less. When the preliminary polishing composition contains a permanganate as the polishing aid while the final polishing composition also contains a permanganate as the polishing aid, the ratio (T_{FIN}/T_{PRE}) of the polishing time T_{FIN} [min] for the final polishing to the polishing time T_{PRE} [min] for the preliminary polishing is typically 1.0 or less. By setting the allocation of the polishing time between the preliminary polishing and the final polishing within the above range, a surface with excellent smoothness tends to be efficiently obtained.

The total time of the preliminary polishing and the final polishing (total polishing time) is not particularly limited. According to the polishing method disclosed herein, when the preliminary polishing composition contains a permanganate as the polishing aid while the final polishing composition contains a vanadate as the polishing aid, polishing with the total polishing time of less than 5 hours can achieve a surface with excellent smoothness in a super-hard material. In a preferred embodiment, polishing with the total polishing time of less than 3 hours (for example, within 2.5 hours, typically 2 hours or less) can achieve a surface with excellent smoothness in a super-hard material. When the preliminary polishing composition contains a permanganate as the polishing aid while the final polishing composition also contains a permanganate as the polishing aid, polishing with the total polishing time of less than 3 hours can achieve a surface with excellent smoothness in a super-hard material. In a preferred embodiment, polishing with the total polishing time of less than 2 hours (for example, within 1.5 hours, typically 1 hour or less) can achieve a surface with excellent smoothness in a super-hard material. It is noted that the total polishing time does not include a time interval between the respective polishing steps (a time during which no polishing is carried out, i.e., non-polishing time). For example, the time after the end of the preliminary polishing step to the start of the final polishing step is not included in the total polishing time.

The preliminary polishing and the final polishing can be applied to both polishing using a single-side polishing machine and polishing using a double-side polishing machine. In the single-side polishing machine, a substrate is affixed to a ceramic plate with wax, or a substrate is held using a holder called a carrier. While a polishing composition is supplied, a polishing pad is pressed against one side of the substrate, and both of the surface and the pad are moved (e.g., rotated) relative to each other, thereby polishing the single side of the substrate. In the double-side polishing machine, a substrate is held using a holder called a carrier. While a polishing composition is supplied from above, respective polishing pads are pressed against opposite surfaces of the substrate, and by rotating them in the relative direction, both surfaces of the substrate are polished at the same time.

The polishing pad used in each polishing step disclosed herein is not particularly limited. For example, any polishing pad of a non-woven fabric type, a suede type, a hard foamed polyurethane type, a type containing abrasives, and a type containing no abrasives may be used.

The substrate polished by the method disclosed herein is typically cleaned after the polishing. This cleaning can be performed using an appropriate cleaning solution. A cleaning solution to be used is not particularly limited, and known or conventional ones can be appropriately selected and used. The temperature of a cleaning solution is not particularly limited, but is preferably, for example, in the range of 20 to 90° C., and more preferably in the range of 50 to 80° C.

The polishing method disclosed herein may include any other step in addition to the preliminary polishing step and the final polishing step described above. Examples of such a step include a lapping step performed before the preliminary polishing step. The above lapping step is a step of polishing the surface of a substrate by pressing the surface of a polishing platen (for example, a cast iron platen) against the substrate. Therefore, in the lapping step, no polishing pad is used. The lapping step is typically carried out by supplying an abrasive (typically, diamond abrasives) between the polishing platen and the substrate. Furthermore, the polishing method disclosed herein may include an additional step (cleaning step or polishing step) before the preliminary polishing step or between the preliminary polishing step and the final polishing step.

### Preliminary Polishing Composition

### Abrasive A_{PRE}

The preliminary polishing composition disclosed herein typically contains an abrasive A_{PRE}. It is preferable for the preliminary polishing composition to contain the abrasive A_{PRE} from the viewpoint of efficiently achieving excellent smoothness. The kind of the abrasive A_{PRE} that can be contained in the preliminary polishing composition is not particularly limited. For instance, the abrasive A_{PRE} can be inorganic particles, organic particles, or organic-inorganic composite particles. Examples thereof include abrasives substantially composed of any one of oxide particles such as silica particles, alumina particles, cerium oxide particles, chromium oxide particles, titanium dioxide particles, zirconium oxide particles, magnesium oxide particles, manganese dioxide particles, zinc oxide particles, and iron oxide particles; nitride particles such as silicon nitride particles and boron nitride particles; carbide particles such as silicon carbide particles and boron carbide particles; diamond particles; and carbonates such as calcium carbonate and barium carbonate. The abrasives may be used alone or in combination of two or more kinds. Among these, oxide particles such as silica particles, alumina particles, cerium oxide particles, chromium oxide particles, zirconium oxide particles, manganese dioxide particles, and iron oxide particles are preferable because they can form a favorable surface. Among these, alumina particles, zirconium oxide particles, chromium oxide particles, and iron oxide particles are more preferable, and alumina particles are particularly preferable.

As used herein, with regard to the composition of an abrasive, “substantially consisting of X” or being “substantially composed of X” means that the ratio of X to the abrasives (or the purity of X) is 90% or more (preferably 95% or more, more preferably 97% or more, or even more preferably 98% or more, e.g., 99% or more) by weight.

When alumina particles are used as the abrasive A_{PRE}, it is advantageous to set the ratio of alumina particles to the entire abrasives A_{PRE} contained in the preliminary polishing composition to a generally higher value. For example, the ratio of alumina particles to the entire abrasives A_{PRE} contained in the preliminary polishing composition is preferably 70% by weight or more, more preferably 90% by weight or more, and even more preferably 95% by weight or more (e.g., 95 to 100% by weight).

Preferably, the preliminary polishing composition disclosed herein contains substantially no diamond abrasive as the abrasive A_{PRE}. Diamond particles can be a factor limiting the improvement in the smoothness because of their high hardness. In addition, since diamond particles are generally expensive, they cannot be said to be a beneficial material in terms of cost performance, and the dependence on expensive materials such as diamond particles is desirably low in consideration of practical use.

The abrasive A_{PRE} usually has a mean secondary particle diameter of 20 nm or more. From the viewpoint of improving the polishing removal rate, it is preferably 100 nm or more, and more preferably 200 nm or more (for example, 300 nm or more). The abrasive with the above mean secondary particle diameter can more efficiently achieve excellent smoothness. From the viewpoint of securing a sufficient number of particles per unit weight, the maximum mean secondary particle diameter of the abrasives A_{PRE} is appropriate to be about 5000 nm or less. From the viewpoint of improving smoothness, the above mean secondary particle diameter is preferably 3000 nm or less, or more preferably 2000 nm or less (e.g., 800 nm or less).

With regard to the abrasive’s mean secondary particle diameter, for particles of less than 500 nm, it can be determined as the volume mean particle diameter (arithmetic mean diameter by volume; Mv) by dynamic light scattering, for example, using model “UPA-UT151” manufactured by Nikkiso Co., Ltd., whereas for particles of 500 nm or more, it can be determined as the volume mean particle diameter by pore electrical resistance, etc., for example, using model “Multisizer 3” manufactured by Beckman Coulter Inc.

When the preliminary polishing composition contains the abrasive A_{PRE}, the content of the abrasive in the preliminary polishing composition is usually appropriate to be 1% by weight or more from the viewpoint of polishing removal rate. From the viewpoint of improving the polishing removal rate, the content of the abrasive is preferably 3% by weight or more, and more preferably 5% by weight or more. From the viewpoint of achieving favorable dispersibility, the content of the abrasive in the preliminary polishing composition is usually appropriate to be 50% by weight or less, preferably 20% by weight or less, more preferably 10% by weight or less, and even more preferably 8% by weight or less.

### Polishing Aid B_{PRE}

The preliminary polishing composition disclosed herein preferably contains a polishing aid B_{PRE}. The polishing aid B_{PRE} is a component that enhances the effects of preliminary polishing, and water-soluble ones are typically used. The polishing aid B_{PRE} is not to be interpreted in a particularly restrictive manner. However, it is considered to alter the substrate surface (typically oxidative alteration) in the preliminary polishing, resulting in weakening of the substrate surface, which contributes to polishing with the abrasive A_{PRE}. For example, when silicon carbide (SiC) is taken as one of the typical examples of the super-hard material, the polishing aid B_{PRE} in polishing is considered to contribute to the oxidation of SiC, i.e., SiOₓC_{y} conversion. The SiOₓC_{y} has lower hardness than single crystal SiC. In addition, in a super-hard material that has a Vickers hardnesses of 1500 Hv or higher, oxidation reactions can generally result in lower hardness and brittleness. These suggest that the addition of the polishing aid B_{PRE} improves the polishing removal rate and the surface quality of the substrate.

Examples of the polishing aid B_{PRE} include peroxides such as hydrogen peroxide; nitric acid compounds including nitric acid, its salts such as iron nitrate, silver nitrate, and aluminum nitrate, and its complexes such as ceric ammonium nitrate; persulfuric acid compounds including potassium peroxomonosulfate, persulfuric acids such as peroxodisulfuric acid, and its salts such as ammonium persulfate and potassium persulfate; chlorine compounds including chloric acid and its salts, and perchloric acid and its salts such as potassium perchlorate; bromine compounds including bromic acid and its salts such as potassium bromate; iodine compounds including iodic acid and its salts such as ammonium iodate, and periodic acid and its salts such as sodium periodate and potassium periodate; ferrates including ferric acid and its salts such as potassium ferrate; permanganates including permanganate acid and its salts such as sodium permanganate and potassium permanganate; chromates including chromic acid and its salts such as potassium chromate and potassium dichromate; vanadates including vanadic acid and its salts such as ammonium vanadate, sodium vanadate, and potassium vanadate; ruthenates including perrhenium and its salts; molybdates including molybdic acid and its salts such as ammonium molybdate and disodium molybdate; rhenates including perrhenic acid and its salts; and tungstates including tungstic acid and its salts such as disodium tungstate. These can be used alone or in combination of two or more kinds as appropriate. Among these, permanganic acid and its salt, chromic acid and its salt, and ferric acid and its salt are preferable. Sodium permanganate and potassium permanganate are particularly preferable.

In a preferred embodiment, the preliminary polishing composition contains a composite metal oxide as the polishing aid B_{PRE}. Examples of the above composite metal oxides include metal nitrates, ferrates, permanganates, chromates, vanadates, ruthenates, molybdates, rhenates, and tungstates. Among these, ferrates, permanganates, and chromates are more preferable, and permanganates are even more preferable.

In a further preferred embodiment, the above composite metal oxide CMO_{PRE} used contains a monovalent or divalent metal element (but not a transition metal element) and a transition metal element in the fourth period of the periodic table. Preferred examples of the above monovalent or divalent metal element (but not a transition metal element) include Na, K, Mg, and Ca. Among these, Na and K are more preferable. Preferred examples of the transition metal element in the fourth period of the periodic table include Fe, Mn, Cr, V, and Ti. Among these, Fe, Mn, and Cr are more preferable, and Mn is even more preferable.

When the preliminary polishing composition disclosed herein contains a composite metal oxide (preferably a composite metal oxide CMO_{PRE}) as the polishing aid B_{PRE}, it may further contain or may not contain a polishing aid B_{PRE} other than a composite metal oxide. The art disclosed herein can be preferably implemented in an embodiment where a polishing aid B_{PRE} (for example, hydrogen peroxide) other than the composite metal oxide (preferably the composite metal oxide CMO_{PRE}) is not substantially contained, as the polishing aid B_{PRE}.

The content of the polishing aid B_{PRE} in the preliminary polishing composition is usually appropriate to be 0.005 mol/L or more. From the viewpoint of improving polishing removal rate, the content of the polishing aid B_{PRE} in the preliminary polishing composition is preferably 0.008 mol/L or more, and more preferably 0.01 mol/L or more, and may be 0.03 mol/L or more, 0.05 mol/L or more, 0.06 mol/L or more, or 0.07 mol/L or more. From the viewpoint of improving smoothness, the content of the polishing aid B_{PRE} in the preliminary polishing composition is usually appropriate to be 0.5 mol/L or less, preferably 0.3 mol/L or less, and more preferably 0.2 mol/L or less, and may be 0.1 mol/L or less, or 0.09 mol/L or less.

### Other Components

As long as the effects of the present invention are not impaired, the preliminary polishing composition disclosed herein may further contain, as necessary, known additives that can be used for a polishing composition (typically a polishing composition for super-hard materials, for example, a polishing composition for silicon carbide substrates). Examples of the known additives include metal salts, alkali metal salts, alkaline earth metal salts, chelating agents, thickeners, dispersants, pH adjusters, surfactants, inorganic polymers, organic polymers, organic acids, organic acid salts, inorganic acids, inorganic acid salts, anti-corrosive agents, preservative agents, and antifungal agents. Since the content of the additive may be appropriately set according to the purpose of addition thereof and does not characterize the present invention, a detailed description thereof will be omitted.

### Solvent

The solvent used in the preliminary polishing composition is not particularly limited as long as it allows dispersion of the abrasives. As the solvent, ion-exchanged water (deionized water), pure water, ultrapure water, distilled water and the like can be preferably used. The preliminary polishing composition disclosed herein may further contain, as necessary, an organic solvent (a lower alcohol, a lower ketone, etc.) that can be uniformly mixed with water. Normally, water preferably accounts for 90% by volume or more of the solvent in the preliminary polishing composition; water more preferably accounts for 95% by volume or more (typically 99 to 100% by volume).

The preliminary polishing composition is not particularly limited in pH. The pH of the preliminary polishing composition is usually appropriate to be about 2 to 12. The preliminary polishing composition with a pH in this range is likely to achieve a practical polishing removal rate. The pH of the preliminary polishing composition is preferably 2 to 10 and more preferably 3 to 9.5, and may be 4 to 8. In some embodiments, the pH of the preliminary polishing composition may be, for example, 6 to 10 or 8.5 to 9.5.

The method for preparing the preliminary polishing composition disclosed herein is not particularly limited. For instance, the respective components to be contained in the preliminary polishing composition may be mixed with a known mixing device such as a propeller stirrer, ultrasonic disperser, and homo mixer. The mode of mixing these components is not particularly limited. For instance, all the components can be mixed at once or in a suitably prescribed order.

### Final Polishing Composition

### Abrasive A_{FIN}

The final polishing composition disclosed herein may contain an abrasive A_{FIN}. In a preferred embodiment of the art disclosed herein, the final polishing composition contains the abrasive A_{FIN} from the viewpoint of achieving the desired polishing removal rate. For instance, the abrasive A_{FIN} can be inorganic particles, organic particles, or organic-inorganic composite particles. As the abrasive A_{FIN}, one or more kinds of those listed in the above description about the abrasive A_{PRE} can be preferably used. Among these, oxide particles, such as silica particles, alumina particles, cerium oxide particles, chromium oxide particles, zirconium oxide particles, manganese dioxide particles, iron oxide particles, and magnesium oxide particles, are more preferable; silica particles, cerium oxide particles, and manganese dioxide particles are even more preferable; and silica particles is particularly preferable.

The silica particles include colloidal silica, fumed silica, precipitated silica or the like. From the viewpoint of improving smoothness, preferred examples of the silica particles include colloidal silica and fumed silica. Among these, colloidal silica is particularly preferable.

When silica particles are used as the abrasive A_{FIN}, it is generally advantageous to set the ratio of silica particles to the entire abrasives A_{FIN} contained in the final polishing composition to a higher value. For example, the ratio of silica particles to the entire abrasives A_{FIN} contained in the final polishing composition is preferably 70% by weight or more, more preferably 90% by weight or more, and even more preferably 95% by weight or more (e.g., 95 to 100% by weight).

The mean secondary particle diameter of the abrasive A_{FIN} is not particularly limited, but from the viewpoint of polishing removal rate or the like, it is preferably 20 nm or more, more preferably 50 nm or more, and even more preferably 60 nm or more. From the viewpoint of achieving a surface with more smoothness, the mean secondary particle diameter of the abrasive A_{FIN} is appropriate to be 500 nm or less, preferably 300 nm or less, more preferably 200 nm or less, even more preferably 130 nm or less, and particularly preferably 110 nm or less.

When the final polishing composition contains the abrasive A_{FIN}, from the viewpoint of polishing removal rate, the content of the abrasive in the final polishing composition is usually appropriate to be 0.01% by weight or more, and may be 0.1% by weight or more, 1% by weight or more, and 3% by weight or more. From the viewpoint of efficiently improving smoothness, the content of the abrasive is preferably 10% by weight or more, and more preferably 20% by weight or more. From the viewpoint of favorable dispersibility, the content of the abrasive in the final polishing composition is usually appropriate to be 50% by weight or less, and preferably 40% by weight or less.

In another preferred embodiment of the art disclosed herein, the final polishing composition contains no abrasive A_{FIN} from the viewpoint of obtaining a desired surface quality. When using the final polishing composition containing the abrasive A_{FIN}, increasing the processing pressure tends to cause abrasive defects such as scratches on the polishing target surface. According to the polishing method disclosed herein, a surface from which latent defects are suitably eliminated can be achieved efficiently even when using the abrasive-free final polishing composition.

### Polishing Aid B_{FIN}

The final polishing composition disclosed herein preferably contains a polishing aid B_{FIN}. The polishing aid B_{FIN} is a component that enhances the effects of the final polishing, and water-soluble ones are typically used. The polishing aid B_{FIN} is not to be interpreted in a particularly restrictive manner, but as in the polishing aid B_{PRE} in the preliminary polishing described above, the polishing aid B_{FIN} is considered to alter the substrate surface (typically to conduct oxidative alteration) in the final polishing, resulting in weakening of the substrate surface, contributing to the polishing removal rate and the surface quality (particularly, improvement in the smoothness) of the substrate.

As the polishing aid B_{FIN}, one or more kinds of those listed in the above description about the polishing aid B_{PRE} can be preferably used. Among these, vanadic acid and its salt, iodine compounds, molybdic acid and its salt, and tungstic acid and its salt are preferable, and sodium metavanadate, sodium vanadate, and potassium vanadate are particularly preferable.

In a preferred embodiment, the final polishing composition contains a composite metal oxide as the polishing aid B_{FIN}. Examples of the composite metal oxide include metal nitrates, ferrates, permanganates, chromates, vanadates, ruthenates, molybdates, rhenates and tungstates. Among these, ferrates, permanganates, chromates, vanadates, molybdates, and tungstates are more preferable, and permanganates and vanadates are even more preferable.

In a further preferred embodiment, as the above composite metal oxide, a composite metal oxide CMO_{FIN} is used which contains a monovalent or divalent metal element (but not a transition metal element) or ammonia, and a group 5 or group 6 transition metal element of the periodic table. Preferred examples of the above monovalent or divalent metal element (but not a transition metal element) or ammonia include Na, K, Mg, Ca and ammonia. Among these, Na and K are more preferable. The group 5 or group 6 transition metal element of the periodic table is preferably selected from the fourth, fifth and sixth period elements, more preferably selected from the fourth and fifth period elements, and even more preferably selected from the fourth period elements. The above transition metal element is preferably selected from the group 5 elements. Specific examples thereof include V, Nb, Ta, Cr, Mo, and W. Among these, V, Mo and W are more preferable, and V is even more preferable.

When the final polishing composition disclosed herein contains a composite metal oxide (preferably the composite metal oxide CMO_{FIN}) as the polishing aid B_{FIN}, it is preferable that as other polishing aids B_{FIN} besides the composite metal oxide, the final polishing composition further contains an oxygen-containing substance capable of supplying oxygen to the above composite metal oxide (preferably the composite metal oxide CMO_{FIN}). Thus, the composite metal oxide (preferably the composite metal oxide CMO_{FIN}) works to continuously exert its chemical effects, thereby making it possible to significantly improve the polishing removal rate in the final polishing and also to improve the smoothness of a super-hard material. Preferred examples of the oxygen-containing substance include hydrogen peroxide, ozone, and peracids. Among these, hydrogen peroxide is particularly preferable.

The content of the polishing aid B_{FIN} in the final polishing composition is usually appropriate to be 0.005 mol/L or more. From the viewpoint of improving polishing rate, the content of the polishing aid B_{FIN} in the final polishing composition is preferably 0.008 mol/L or more, and more preferably 0.01 mol/L or more, and may be 0.03 mol/L or more, 0.05 mol/L or more, 0.06 mol/L or more, or 0.07 mol/L or more. From the viewpoint of improving smoothness, the content of the polishing aid B_{FIN} in the final polishing composition is usually appropriate to be 0.5 mol/L or less, preferably 0.3 mol/L or less, and more preferably 0.2 mol/L or less, and may be 0.1 mol/L or less, or 0.09 mol/L or less.

As for the polishing aid B_{FIN}, when using both a composite metal oxide (preferably a composite metal oxide CMO_{FIN}) and an oxygen-containing substance capable of supplying oxygen to the metal oxide, the content of the composite metal oxide is usually appropriate to be 0.1% by weight or more. From the viewpoint of improving the polishing rate, the above content is preferably 0.5% by weight or more, and more preferably 1.4% by weight or more. From the viewpoint of improving smoothness, the content of the above composite metal oxide is usually appropriate to be 10% by weight or less, preferably 3% by weight or less, and more preferably 2.5% by weight or less. In that case, the content of the above oxygen-containing substance is normally appropriate to be 0.1 to 10% by weight. From the viewpoint of suitably exerting an oxygen supplying effect, the above content is preferably 0.5 to 3% by weight, and more preferably 1 to 2% by weight.

The final polishing composition is not particularly limited in pH. The pH of the final polishing composition is usually appropriately to be about 2 to 12. The final polishing composition having a pH in this range is likely to efficiently achieve excellent smoothness. The final polishing composition has a pH of preferably 2 to 10, and more preferably 3 to 8. In some embodiments, the pH of the final polishing composition may be higher than the pH of the preliminary polishing composition. This can be advantageous from the viewpoint of achieving both improvement in the surface quality and adequate productivity. For example, the pH of the final polishing composition may be higher than the pH of the preliminary polishing composition by about 0.2 to 2.0 or about 0.5 to 1.5.

As for other components and solvents that can be used in the final polishing composition, those which can be included in the preliminary polishing composition can be preferably adopted, and thus a duplicate description thereof is not given herein. The final polishing composition can be prepared, for instance, by employing a similar method as the preparation method for the preliminary polishing composition described above or by making a suitable modification based on the technical common knowledge among those ordinarily skilled in the art.

### Polishing Composition Kit

The art disclosed herein may include, for instance, providing a polishing composition kit as following. That is, the art disclosed herein provides the polishing composition kit including the preliminary polishing composition and the final polishing composition. The above preliminary polishing composition can be a polishing slurry or its concentrate that is used in the preliminary polishing step of the polishing method disclosed herein. The above final polishing composition can be a polishing slurry or its concentrate that is used in the final polishing step of the polishing method disclosed herein. According to the above polishing composition kit, a super-hard material surface with excellent smoothness can be efficiently achieved in a multi-step polishing process. Such a polishing composition kit can contribute to a decrease in polishing time and an improvement in productivity. In the polishing composition kit disclosed herein, the preliminary polishing composition and the final polishing composition are preferably stored separately from each other.

### Manufacturing Method of Substrate

The art disclosed herein may include, for instance, providing a manufacturing method of a substrate. That is, according to the art disclosed herein, the manufacturing method of a substrate is provided which includes: a step of carrying out preliminary polishing on a substrate made of a material that has a Vickers hardness of 1500 Hv or higher on at least its surface using a preliminary polishing composition; and a step of carrying out final polishing on the preliminarily polished substrate using a final polishing composition. The above manufacturing method can be implemented by suitably applying the contents of the polishing method disclosed herein. According to the above manufacturing method, a substrate having a super-hard material surface with excellent smoothness, from which latent defects are eliminated, is efficiently provided.

### EXAMPLES

Several examples relating to the present invention will be described below, but the present invention is not intended to be limited to those described in the examples. Here, in the following description, “%” is on a weight basis, unless otherwise specified.

### Preparation of Polishing Composition

### Examples 1 And 2 And Comparative Examples 1 And 2

### Preparation Of Preliminary Polishing Composition

Alumina particles as the abrasive, potassium permanganate as the polishing aid, and deionized water were mixed together to prepare a preliminary polishing composition. The mean secondary particle diameter of the used aluminum particles was about 400 nm. In the preliminary polishing composition, the content of the abrasive was 6%, and the content of potassium permanganate was 0.08 M (0.08 mol/L). The pH of the preliminary polishing composition was 5.6.

### Preparation of Final Polishing Composition

Colloidal silica as the abrasive, hydrogen peroxide and a vanadate as the polishing aids, and deionized water were mixed together, followed by addition of potassium hydroxide to prepare a final polishing composition of pH 6.5. The mean secondary particle diameter of the used colloidal silica was about 80 nm. In the final polishing composition, the content of the abrasive was 23%, the content of hydrogen peroxide was 2%, and the content of vanadate was 1.5%.

### Examples 3 and 4 and Comparative Examples 3 and 4

The preliminary polishing composition was prepared in the same manner as in Example 1 to produce a preliminary polishing composition according to the present example. Regarding the final polishing composition, a final polishing composition of pH 6.5 was prepared in the same way as in Example 1 except that no abrasive was used and potassium permanganate was used as the polishing aid. In the final polishing composition, the content of potassium permanganate was 0.08 M (0.08 mol/L).

### Evaluation Tests

### Preliminary Polishing

A SiC wafer previously subjected to lapping using diamond abrasives with a mean particle diameter of 5 µm was prepared. The surface of the SiC wafer was polished using the prepared preliminary polishing slurry on the following preliminary polishing conditions.

### Preliminary Polishing Conditions

Polishing machine: model “RDP-500”, a single-side polishing machine manufactured by Fujikoshi Machinery Corp.
Polishing pad: “SUBA800XY” manufactured by Nitta Haas Incorporated
Polishing pressure: 29.4 kPa
Platen rotational speed: 100 rpm
Head rotational speed: 100 rpm
Flow rate of polishing slurry: 20 mL/minute (used in one-way)
Temperature of polishing slurry: 25° C.
Substrate: SiC wafer (conduction type: n-type, crystalline type 4H-SiC, off angle with respect to the C axis of the main surface (0001):4°), 2 inches
Polishing time: 1 hour

### Final Polishing

Then, the surface of the SiC wafer subjected to the preliminary polishing was polished using the prepared final polishing slurry on the following final polishing conditions.

### Final Polishing Conditions

Polishing machine: model “RDP-500”, a single-side polishing machine manufactured by Fujikoshi Machinery Corp.
Polishing pad: “SUBA800” manufactured by Nitta Haas Incorporated
Polishing pressure: 300 g/cm²
Platen rotational speed: 80 rpm
Head rotational speed: 40 rpm
Flow rate of polishing slurry: 20 mL/minute (used in one-way)
Temperature of polishing slurry: 25° C.

### Number of Latent Defects

Regarding the substrate surface obtained after the final polishing according to each example, the surface was observed at a viewing angle of 10 µm × 10 µm using an atomic force microscope (AFM; model XE-HDM, manufactured by Park Systems Corporation) to detect defects. The number of defects with a size of 20 Å or more in the depth direction (i.e., in the wafer thickness direction) was counted to determine the number of latent defects. The results are shown in Table 1.

### Surface Roughness Ra

Regarding the substrate surface obtained after the preliminary polishing according to each example, the surface roughness of the surface was measured at 22 points in the surface plane under the condition of a measurement region of 10 µm × 10 µm using the atomic force microscope (AFM; model XE-HDM, Park Systems Corporation). The average value of the measured surface roughnesses was determined as the surface roughness Ra_{PRE} (nm). Regarding the surface of the substrate obtained after the final polishing according to each example, the surface roughness of the surface was measured at 22 points in the substrate plane under the condition of a measurement region of 10 µm × 10 µm using the same atomic force microscope as that used in the measurement of the surface roughness Ra_{PRE}. The average value of the measured surface roughnesses was determined as the surface roughness Ra_{FIN} (nm). The results are shown in Table 1.

### Polishing Removal

In the preliminary polishing according to each example, a polishing removal W_{PRE} was calculated based on formula (b) below. As a result, the polishing removal W_{PRE} of the preliminary polishing was about 1.5 µm. In the final polishing according to each example, a polishing removal W_{FIN} was calculated based on formula (b) below. The results are shown in Table 1.

(b) polishing removal [cm] = a difference in weight of a SiC wafer before and after polishing [g]/density of SiC [g/cm³] (= 3.21 g/cm³)/polishing target area [cm²] (= 19.62 cm²)

TABLE 1

| | Preliminary polishing | | Surface roughness Ra_{PRE} [nm] | Final polishing | | | | Surface roughness Ra_{FIN} [nm] | Number of blind scratches [pieces] |
|---|---|---|---|---|---|---|---|---|---|
| | Abrasive | Polishing aid | | Abrasive | Polishing aid | Polishing time T_{FIN} [min] | Polishing removal W_{FIN} [µm] | | |
| Ex. 1 | Al₂O₂ | KMnO₄ | 0.06 | SiO₂ | H₂O₂, NaVO₃ | 60 | 0.3 | 0.04 | 0 |
| Ex. 2 | Al₂O₃ | KMnO₄ | 0.06 | SiO₂ | H₂O₂, NaVO₃ | 90 | 0.45 | 0.04 | 0 |
| Ex. 3 | Al₂O₃ | KMnO₄ | 0.06 | - | KMnO₄ | 20 | 0.3 | 0.04 | 0 |
| Ex. 4 | Al₂O₃ | KMnO₄ | 0.06 | - | KMnO₄ | 30 | 0.45 | 0.04 | 0 |
| Comp. Ex. 1 | Al₂O₃ | KMnO₄ | 0.06 | SiO₂ | H₂O₂, NaVO₃ | 10 | 0.05 | 0.08 | 5 |
| Comp. Ex. 2 | Al₂O₃ | KMnO₄ | 0.06 | SiO₂ | H₂O₂, NaVO₃ | 30 | 0.15 | 0.1 | 10 |
| Comp. Ex. 3 | Al₂O₃ | KMnO₄ | 0.06 | - | KMnO₄ | 3 | 0.05 | 0.08 | 5 |
| Comp. Ex. 4 | Al₂O₃ | KMnO₄ | 0.06 | - | KMnO₄ | 10 | 0.15 | 0.1 | 10 |

As shown in Table 1, it is confirmed that according to the polishing methods of Examples 1 to 4, since the surface roughness Ra_{PRE} was adjusted to 0.1 mm or less by the preliminary polishing, and the final polishing was carried out to achieve the polishing removal W_{FIN} of 3.0 µm or more, the number of latent defects on the substrate surface was significantly decreased, and the surface roughness Ra_{FIN} was reduced, resulting in an improvement in the smoothness, compared to Comparative Examples 1 to 4.

While specific examples of the present invention have been described above in detail, these are only examples, and do not limit the scope of the claims. The art recited in the claims includes various modifications and alternations of the specific examples exemplified above.

1. A method for polishing a substrate made of a material having a Vickers hardness of 1500 Hv or higher, the method comprising:
a step of carrying out preliminary polishing on the substrate using a preliminary polishing composition; and
a step of carrying out final polishing on the preliminarily polished substrate using a final polishing composition,
wherein a surface roughness Ra_{PRE} of the preliminarily polished substrate measured by an AFM is 0.1 nm or less, and
wherein a polishing removal in the final polishing step is 0.3 µm or more.

2. The polishing method according to claim 1, wherein the preliminary polishing composition contains alumina particles as an abrasive A_{PRE}.

3. The polishing method according to claim 1, wherein the preliminary polishing composition contains a composite metal oxide as a polishing aid B_{PRE}.

4. The polishing method according to claim 1, wherein the final polishing composition contains no abrasive A_{FIN} or contains silica particles as an abrasive A_{FIN}.

5. The polishing method according to claim 1, wherein the final polishing composition contains a composite metal oxide as a polishing aid B_{FIN}.

6. A polishing composition kit used in the polishing method according to claim 1,
comprising: the preliminary polishing composition; and the final polishing composition,
wherein the preliminary polishing composition contains alumina particles as an abrasive A_{PRE}, and
wherein the final polishing composition contains no abrasive A_{FIN} or contains silica particles as an abrasive A_{FIN}.

7. The polishing method according to claim 1, wherein the preliminary polishing composition contains silica particles as an abrasive A_{PRE}.

8. The polishing method according to claim 3, wherein the composite metal oxide contains permanganates.

9. The polishing method according to claim 5, wherein the composite metal oxide contains permanganates.

10. The polishing method according to claim 5, wherein the composite metal oxide contains vanadates.

11. The polishing method according to claim 1, wherein the final polishing composition contains no abrasive A_{FIN}.

12. The polishing method according to claim 1, wherein the final polishing composition contains alumina particles as an abrasive A_{FIN}.

13. The polishing method according to claim 8, wherein the permanganate is sodium permanganate.

14. The polishing method according to claim 9, wherein the permanganate is potassium permanganate.

15. The polishing method according to claim 3, wherein the composite metal oxide contains metal nitrates.

16. The polishing method according to claim 5, wherein the composite metal oxide contains metal nitrates.
